(19) United States
(12) Patent Application Publication
(10) Pub. No.: US 2016/0170247 A1
(43) Pub. Date: Jun. 16, 2016

(54) Display with Spacer Ring

(71) Applicant: Apple Inc., Cupertino, CA (US)

(72) Inventors: Mohd Fadzli A. Hassan, Cupertino, CA (US); Jin Yan, Santa Clara, CA (US); Myunghun Lee, Cupertino, CA (US); Nathan K. Gupta, San Francisco, CA (US); Xinyu Zhu, Cupertino, CA (US); Young Cheol Yang, Sunnyvale, CA (US); Yu-Cheng Chen, San Jose, CA (US)

(21) Appl. No.: 14/862,004

(22) Filed: Sep. 22, 2015

Related U.S. Application Data
(60) Provisional application No. 62/091,278, filed on Dec. 12, 2014.

(51) Int. Cl. G02F 1/1339; G02F 1/1335; G02F 1/1368; H01L 27/12

(52) U.S. Cl. CPC G02F 1/1339; H01L 27/1259; G02F 1/13394; G02F 1/133514; G02F 1/133512; G02F 1/1368

(57) ABSTRACT

A display may have a layer of liquid crystal material interposed between a color filter layer and a thin-film transistor layer. A ring of adhesive sealant may surround the liquid crystal layer. Columns spacers may extend between the color filter and thin-film transistor layers through the liquid crystal layer to help ensure that the color filter and thin-film transistor layers are appropriately spaced apart from each other. A ring-shaped polymer spacer may surround the ring of adhesive sealant and may help protect display structures form exposure to etchant that is used to treat the edges of glass layers in the display. The spacer may be formed from the same layer of material that forms the column spacers. A black masking layer may be formed on the underside of the color filter layer using techniques that prevent the formation of protruding edge portions.

This application claims priority to U.S. provisional patent application No. 62/091,278 filed Dec. 12, 2014, which is hereby incorporated by reference herein in its entirety.

### BACKGROUND

This relates generally to electronic devices with displays, and, more particularly, to processing edges in displays to enhance display strength.

Electronic devices often include displays. A display may have glass substrates. For example, a liquid crystal display may have a glass color filter layer substrate and a glass thin-film transistor layer substrate. During manufacturing, the edges of a glass substrate may be ground using a grinding tool. The grinding tool may create microcracks along the edges of the display that can weaken the display. To strengthen the display, it may be desirable to remove the microcracks. If care is not taken, however, liquids that are used during microcrack removal may penetrate the edges of the display and cause damage to metal traces and other display structures.

It would therefore be desirable to be able to provide improved methods of forming displays with ground edges for use in electronic devices.

### SUMMARY

An electronic device may have a display. The display may have an upper layer such as a color filter layer and a lower layer such as a thin-film transistor layer. A liquid crystal layer may be interposed between the upper and lower layers. A ring of adhesive sealant may surround the liquid crystal layer to retain the liquid crystal layer between the upper and lower layers. Columns spacers may extend between the upper and lower layers through the liquid crystal layer to help ensure that the upper and lower layers are separated from each other by a desired distance.

A ring-shaped polymer spacer may surround the ring of adhesive sealant. The spacer may form a seal with the color filter layer and thin-film transistor layer when compressed between the color filter layer and the thin-film transistor layer. The presence of the spacer may help prevent etchant or other materials form entering the edge of the display. The etchant may be used to smooth peripheral edges of glass layers in the display to help minimize grinding microcracks that might otherwise weaken the display.

The spacer may be formed from the same layer of material that forms the column spacers. For example, the column spacers and the ring-shaped spacer may be formed from a photoimageable polymer such as photoimageable acrylic and may be patterned using photolithography.

A black masking layer may be formed on the underside of the color filter layer using techniques that prevent the formation of unsightly protruding black masking layer portions. The black masking layer may be formed from a photoimageable polymer. If desired, an edge portion of the masking layer may be formed from metal. The metal may have a ring shape that runs along the edges of the display. Dielectric may be interposed between the metal and a layer of black masking polymer to prevent electrostatic charge from disrupting display operation.

During processing, a portion of a color filter layer may be retained on a display panel to protect metal traces in a thin-film transistor ledge region of the thin-film transistor layer during acid etching of the display edges. Following etching, the portion of the color filter layer in the ledge region may be removed from the display panel using techniques such as scribing and breaking techniques.

### BRIEF DESCRIPTION OF THE DRAWINGS

FIG. 1 is a schematic diagram of an illustrative electronic device having a display in accordance with an embodiment.

FIG. 2 is a cross-sectional side view of an illustrative display in an electronic device in accordance with an embodiment.

FIG. 3 is a cross-sectional side view of a display having a thin-film transistor layer ledge region in accordance with an embodiment.

FIG. 4 is cross-sectional side view of an illustrative display showing the display may have a color filter layer opening in accordance with an embodiment.

FIG. 5 is a cross-sectional side view of an edge portion of the display showing how a spacer may be used to prevent damage to the display when processing the edge of the display in accordance with an embodiment.

FIG. 6 is flow chart of illustrative steps involved in forming a display in accordance with an embodiment.

FIG. 7 is a cross-sectional side view of an illustrative display with a spacer before processing the edge of the display in accordance with embodiment.

FIG. 8 is a cross-sectional side view of the display of FIG. 7 after processing the edge of the display in accordance with embodiment.

FIG. 9 is a cross-sectional side view of an edge portion of an illustrative display having a peripheral metal opaque masking layer structure in a configuration before the edge of the display has been processed in accordance with an embodiment.

FIG. 10 is a cross-sectional side view of the display of FIG. 9 after the edge of the display has been processed in accordance with an embodiment.

FIG. 11 is a cross-sectional side view of edge portion of another illustrative display having a peripheral metal opaque masking layer structure before processing the edge of the display in accordance with an embodiment.

FIG. 12 is a cross-sectional side view of the edge portion of the illustrative display of FIG. 11 after etching in accordance with an embodiment.

FIG. 13 is a cross-sectional side view of the edge portion of the illustrative display of FIG. 12 after metal etching to remove protruding metal from the edge portion in accordance with an embodiment.

### DETAILED DESCRIPTION

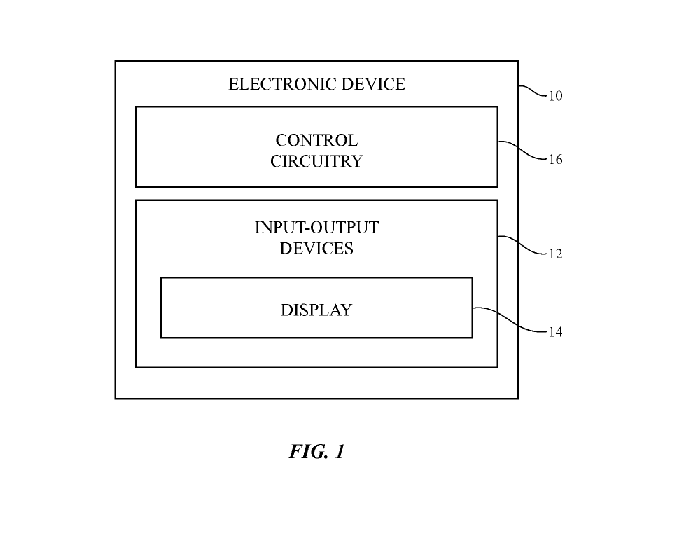

An illustrative electronic device of the type that may be provided with a display is shown in FIG. 1. As shown in FIG. 1, electronic device 10 may have control circuitry 16. Control circuitry 16 may include storage and processing circuitry for supporting the operation of device 10. The storage and processing circuitry may include storage such as hard disk drive storage, nonvolatile memory (e.g., flash memory or other electrically-programmable-read-only memory configured to form a solid state drive), volatile memory (e.g., static or dynamic random-access-memory), etc. Processing circuitry in control circuitry 16 may be used to control the operation of device 10. The processing circuitry may be based on one or more microprocessors, microcontrollers, digital signal processors, baseband processors, power management units, audio chips, application specific integrated circuits, etc.

Input-output circuitry in device 10 such as input-output devices 12 may be used to allow data to be supplied to device 10 and to allow data to be provided from device 10 to external devices. Input-output devices 12 may include buttons, joysticks, scrolling wheels, touch pads, key pads, keyboards, microphones, speakers, tone generators, vibrators, cameras, sensors, light-emitting diodes and other status indicators, data ports, etc. A user can control the operation of device 10 by supplying commands through input-output devices 12 and may receive status information and other output from device 10 using the output resources of input-output devices 12.

Input-output devices 12 may include one or more displays such as display 14. Display 14 may be a touch screen display that includes a touch sensor for gathering touch input from a user or display 14 may be insensitive to touch. A touch sensor for display 14 may be based on an array of capacitive touch sensor electrodes, acoustic touch sensor structures, resistive touch components, force-based touch sensor structures, a light-based touch sensor, or other suitable touch sensor arrangements.

Control circuitry 16 may be used to run software on device 10 such as operating system code and applications. During operation of device 10, the software running on control circuitry 16 may display images on display 14.

Device 10 may be a tablet computer, laptop computer, a desktop computer, a television, a cellular telephone, a media player, a wristwatch device or other wearable electronic equipment, or other suitable electronic device.

Display 14 may be a liquid crystal display, an organic light-emitting diode display, an electrophoretic display, an electrowetting display, or any other suitable type of display. Configurations in which display 14 is a liquid crystal display are sometimes described herein as an example. This is, however, merely illustrative. Any suitable type of display may be used, if desired.

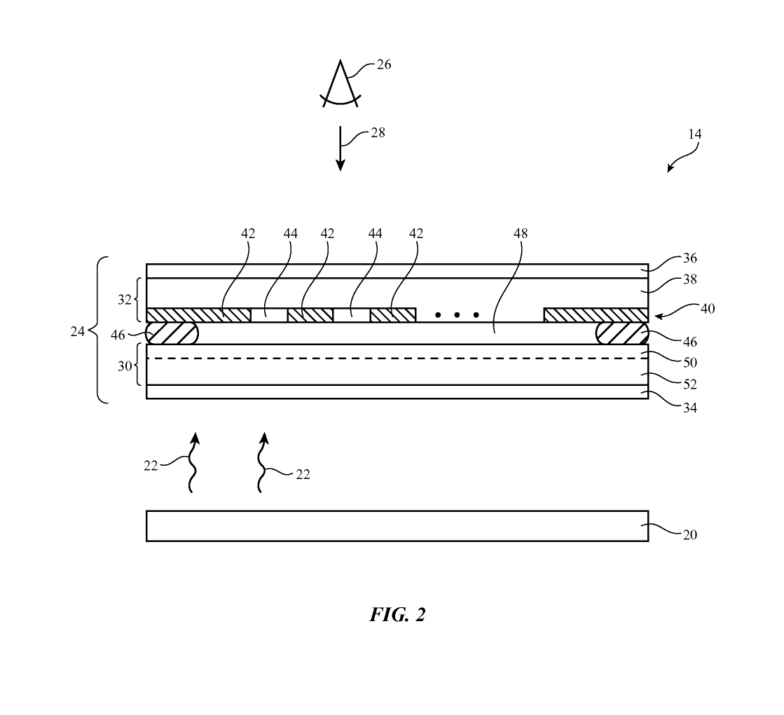

Display 14 may have a rectangular shape (i.e., display 14 may have a rectangular footprint and a rectangular peripheral edge that runs around the rectangular footprint) or may have other suitable shapes. A cross-sectional side view of an illustrative liquid crystal display is shown in FIG. 2. As shown in FIG. 2, display 14 may include a layer of liquid crystal material such as layer 48 sandwich between upper substrate 32 lower substrate 30. Upper substrate 32 may be a color filter layer. Lower substrate 30 may be a thin-film transistor layer. Layers 30 and 32 may contain planar glass layers, plastic glass layers, sapphire layers, ceramic substrates, or other suitable substrate materials.

During operation of display 14, backlight unit 20 may produce backlight illumination 22. Backlight 22 travels through display layers 24 to illuminate images that are being produced by layers 24 for a viewer such as viewer 26 who is viewing display 14 in direction 28. Display layers 24 may include lower polarizer 34 and upper polarizer 36. Substrate layers 30 and 32 and liquid crystal layer 48 may be sandwiched between lower polarizer 34 and upper polarizer 36. A peripheral ring of sealant such as sealant 46 may be used to retain liquid crystal material 48 within display 14. Sealant 46 may be formed from an adhesive such as epoxy or other suitable material.

Display layers 24 may contain color filter elements that allow display 14 to display color images for viewer 26. Thin-film transistor circuitry may be used to control how electric fields are applied to pixels of liquid crystal material in the display. The thin-film transistor circuitry may have an array of electrodes associated with an array of respective pixel circuits for the pixels of display 14. The thin-film transistor circuitry and color filter elements may be provided on a single substrate layer or on separate substrate layers. With one suitable arrangement, which is sometimes described herein is an example, upper substrate layer 32 is a color filter layer and lower substrate layer 30 is a thin film transistor layer. Other configurations may be used for display 14 if desired.

Color filter layer 32 may include glass substrate 38. Color filter element layer 40 may include color filter elements 44. Color filter elements 44 may include red color filter elements, green color filter elements, and blue color filter elements or may include color filter elements of other colors. Color filter element layer 40 may also include opaque masking material such as black masking material 42. Display 14 may have a central active region which black masking layer 42 is patterned to form a black matrix. The black matrix may have a grid shape with openings that receive respective color filter elements. Display 14 may also have a peripheral rectangular-ring-shaped inactive region in which black masking layer 42 forms an opaque border for display 14. Thin-film transistor layer 30 may include glass substrate 52.

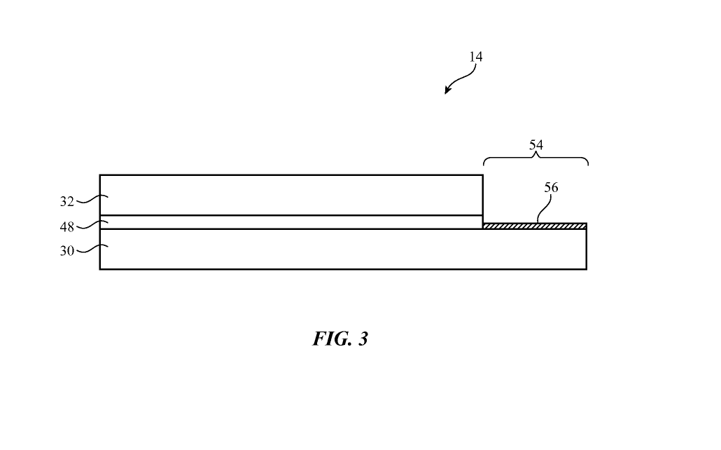

If desired, display 14 may have a thin-film transistor ledge region such as region 54 of FIG. 3. As shown in FIG. 3, liquid crystal material 48 may be sandwiched between thin-film transistor layer 30 and color filter layer 32. Traces 56 may be formed in ledge region 54 and elsewhere on the surface of the glass substrate layer in thin-film transistor layer 30. A portion of color filter layer 32 may be removed in ledge region 54 to form the thin-film transistor ledge and thereby expose traces 56. A flexible printed circuit may be attached to the traces in ledge region 54 and/or a display driver integrated circuit or other integrated circuit may be mounted to the traces in ledge region 54. For example, an integrated circuit or other electrical device may be soldered to traces 56 or a flexible printed circuit cable or other signal path may be attached to traces 56 using anisotropic conductive film or other conductive adhesive.

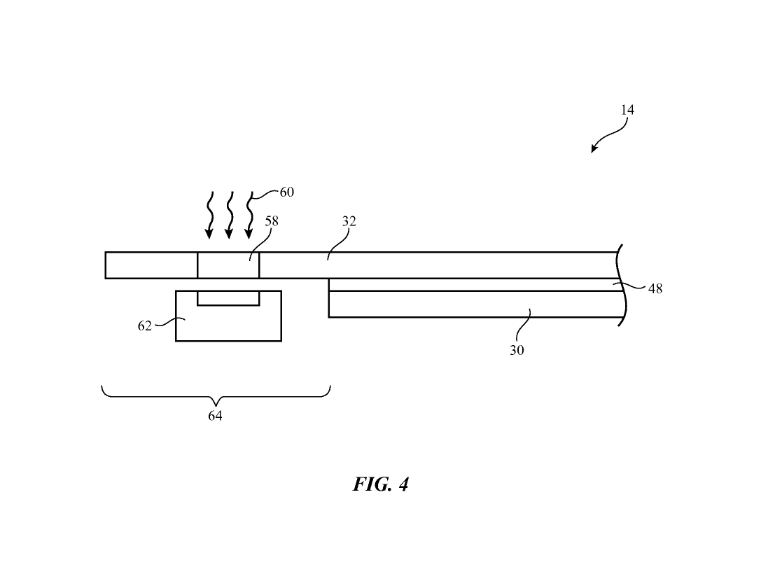

As shown in the cross-sectional side view of display 14 in FIG. 4, a portion of color filter layer 32 such as portion 64 may overhang the edge of thin-film transistor layer 30. An opening such as opening 58 may be formed in layer 32 (e.g., in the glass substrate of layer 32). A component such as component 62 may mounted within device 10 in alignment with opening 58. Opening 58 may allow signals 60 such as light or sound signals to pass-through opening 58. Component 62 may be a camera, a microphone, a speaker, another light-based or acoustic component, or other electrical device.

The glass substrate layers of display 14 may be formed from large motherglass panels. During manufacturing, scribing and breaking techniques, laser-based cutting techniques, or other cutting techniques may be used to divide the motherglass panels into smaller individual display panels. Grinding techniques may be used to smooth and to impart a desired edge profile to the scribed-and-broken display edges. The scribing and breaking process and the edge grinding process may create small cracks along the edge of the glass layers. These cracks, which may sometimes be referred to as microcracks, may weaken the glass substrate layers of display 14. Chemical and/or mechanical polishing techniques may be used to remove or at least blunt the microcracks so that the display is strengthened sufficiently to withstand impacts during drop events and other stresses during use for device 10. For example, the edges of the display may be exposed to a glass etchant such as hydrofluoric acid (HF).

There is potential for damage to exposed metal traces and other structures around the edge of a display if these structures are exposed to an acid such as HF. To prevent damage from HF exposure, display 14 may be provided with a peripheral ring-shaped spacer structure that surrounds ring-shaped sealing structure 46.

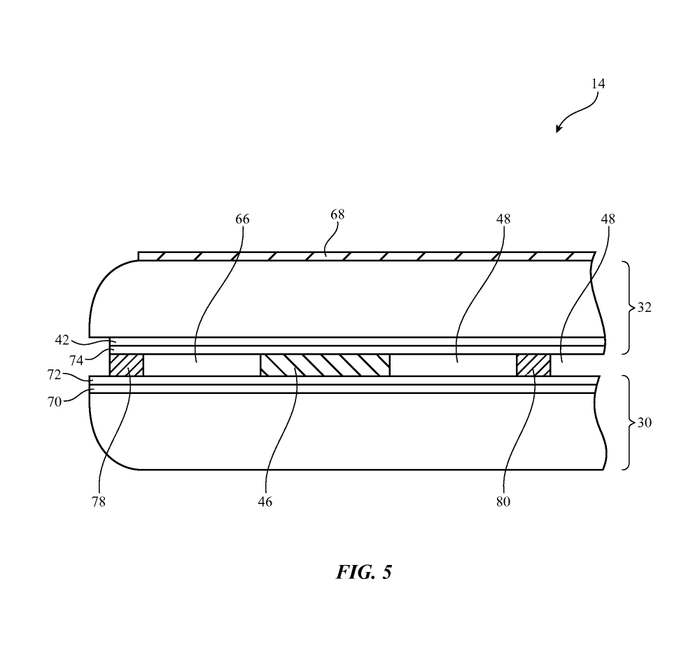

An illustrative configuration for display 14 in which display 14 has been provided with a spacer is shown in FIG. 5. As shown in FIG. 5, liquid crystal layer 48 may be interposed between thin-film transistor layer 30 and color filter layer 32. A ring of sealant 46 such as epoxy or other adhesive may be used to seal liquid crystal material 48 within displayed 14. Spacer 78 may surround sealant 46.

Thin-film transistor layer 30 may have coating layers such as inorganic buffer layer 70 and passivation layer 72. Buffer layer 70 may be a layer of inorganic material such as silicon nitride. Passivation layer 72 may be formed from an organic layer of material such as a layer of acrylic or other polymer.

The upper surface of color filter layer 32 may be coated with an electrostatic discharge protection layer such as indium tin oxide layer 68. The lower surface of color filter layer 32 may be coated with an opaque masking material such as black masking layer 42. Layer 42 may be coated with acrylic overcoat layer 74. Black masking layer 42 may be formed from an opaque photoimageable polymer such as a polymer containing a black material such as carbon black.

To ensure that an appropriate distance is maintained between color filter layer 32 and thin-film transistor layer 30, display 14 may be provided with column spacers such as column spacer 80. Column spacers 80 may be patterned from a layer of photoimageable polymer such as a layer of photoimageable acrylic. An array of column spacers 80 may pass through liquid crystal layer 48 and may help separate layers 30 and 32 from each other.

Spacer 78 may be formed from the same layer of material that is used to form column spacers 80. Spacer 78 may have the shape of a rectangular ring that runs around the edge of display 14 between layers 32 and 30. Sealant 46 is preferably an adhesive and forms adhesive bonds between layers 30 and 32. In contrast, spacer 78 need not be an adhesive material. Rather, spacer 78 may be patterned on layer 32 using photolithography and may form a seal with layer 30 due to compressive force between layers 30 and 32. The presence of spacer 78 helps prevent HF and other corrosive processing liquids from intruding into the edge region of display 14 while the HF is being used to etch the glass layers display 14 and thereby remove microcracks from the edge of display 14. In particular, spacer 78 prevents HF and other liquids from reaching edge region 66 of display 14 and sealant 46. This helps protect traces and other structures on the surfaces of the layers of display 14 in region 66 from damage. Column spacers 80 and peripheral spacer 78 may be patterned simultaneously using photolithographic processing techniques. As a result, no additional processing steps are needed to create spacer 78. Because photolithographic processing techniques are used, spacer 78 may be accurately positioned along the edge of display 14. In a rectangular display, seal 46 and spacer 78 may have concentric rectangular ring shapes.

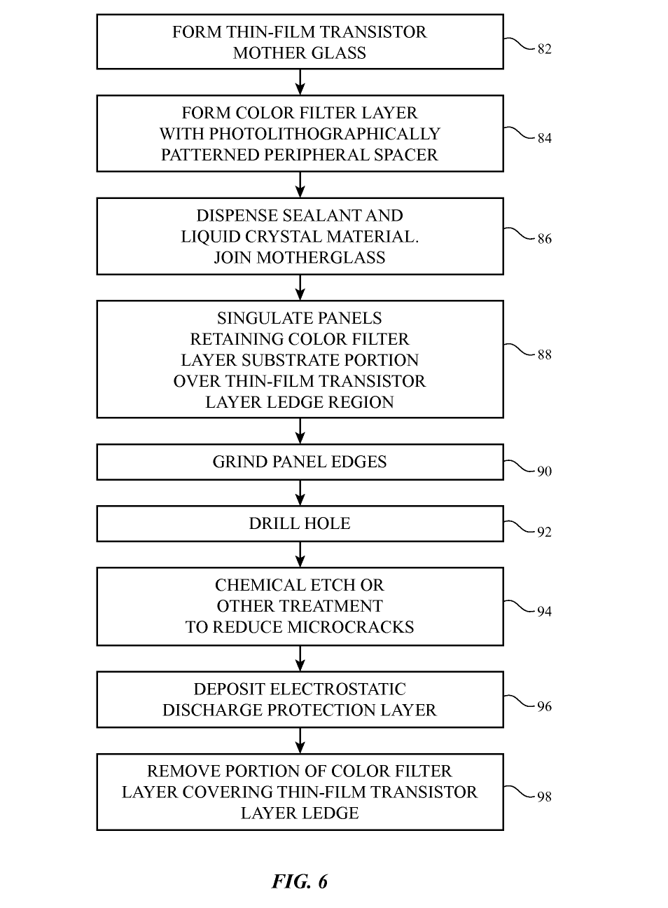

FIG. 6 is a flowchart of illustrative steps involved in forming display 14.

At step 82, a thin-film transistor motherglass layer may be formed. The thin-film transistor motherglass may contain sufficient thin-film transistor circuitry to form multiple displays. The thin film transistor circuitry may include polysilicon thin-film transistors, semiconducting-oxide thin-film transistors, metal traces, dielectric layers, buffer layers, passivation layers, and other thin film transistor circuit structures.

At step 84, a color filter layer motherglass layer may be formed. The color filter motherglass may contain color filter elements 44, black masking material 42, and other color filter layer structures such as acrylic overcoat layer 74. As part of the process of forming the color filter layer motherglass, photolithographic processing techniques may be used to simultaneously form column spacers 80 and peripheral spacers 78.

At step 86, a ring of sealant 46 may be dispensed around each panel location within the motherglass and liquid crystal material 48 may be dispensed within each ring of sealant 46. The thin-film transistor motherglass and the color filter motherglass may then be pressed together. Sealant 46 may be cured (e.g., by exposure to ultraviolet light, etc.).

At step 88, scribing and breaking techniques and/or laser cutting techniques or other cutting techniques may be used to singulate the motherglass into individual display panels. During singulation, the portion of color filter layer 32 in ledge region 54 in each panel may be retained. This portion of color filter layer 32 will cover metal traces 56 on thin-film transistor layer 30 during subsequent processing in HF or other processing substances. Because this portion of color filter layer 32 is present, traces 56 on ledge 54 may be protected without using additional masking materials.

At step 90, a grinding tool may be used to grind edges of each display panel. The grinding tool may use a curved bit so that the edges of the display have a rounded appearance or bits of other shapes may be used to smooth the edges of the display. The display may have glass substrate layers (e.g., the color filter layer and/or the thin-film transistor layer may be formed from glass substrates) or substrate materials of other types may be used. If desired, features such as opening 58 of FIG. 4 may be formed at step 92 using the grinding tool, a drill, or other equipment. For example, a grinding tool may be used to grind opening 58 within an overhanging portion of layer 32 such as portion 64 of FIG. 4.

The grinding processes of steps 90 and 92 create microcracks along the edges of the display glass layers such as color filter layer 32 and create microcracks within opening 58. The presence of microcracks may weaken display 14. Accordingly, at step 94, HF etching or other chemical or mechanical smoothing techniques may be used to remove or modify the microcracks to strength display 14. Because a portion of color filter layer 32 is present in ledge region 54, traces 56 are not exposed to HF or other potentially corrosive materials during the processing operations of step 94. Electrostatic discharge protection layer 68 is preferably not present during the processing of step 94 so that the indium tin oxide or other material used to form layer 68 is not exposed to HF. The presence of spacer 78 ensures that HF will not penetrate into region 66 and thereby ensures that display structures in region 66 will not be damaged during microcrack removal.

Following processing at step 94, color filter layer 32 may be coated with electrostatic discharge protection layer 68 (step 96). For example, a layer of indium tin oxide may be deposited as a coating on top of color filter layer 32. The electrostatic discharge protection layer helps dissipate static charge that might otherwise build up on the surface of display 14 during use.

At step 98, laser cutting techniques, scribing and breaking techniques, or other techniques may be use to remove the portion of color filter layer 32 in thin-film transistor ledge region 54. This exposes traces 56 in thin-film transistor ledge region 54 and allows display 14 to be electrically coupled to other components in device 10.

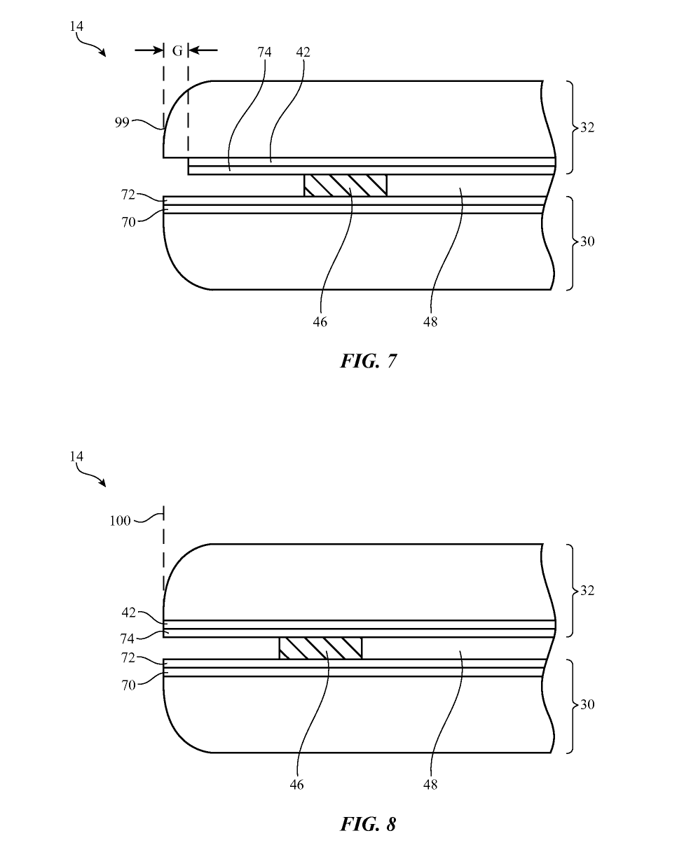

There is a potential for the coating layers on color filter layer 32 in display 14 to protrude from the edge of display 14 following chemical etching of the glass substrates with HF. For example, HF may not remove black masking layer 42 and acrylic overcoat layer 74 along the edge of color filter layer 32 while the HF is etching away the glass substrate of color filter layer 32. Unsightly coating protrusions can be avoided by patterning the coating layers so that the coating layers do not extend all the way to the edge of color filter layer substrate 32 before HF exposure. Consider, as an example, the illustrative configuration of display 14 in FIG. 7. As shown in FIG. 7, the innermost surface of color filter layer 32 may be coated with black masking layer 42 and acrylic overcoat layer 74. Prior to exposure to HF, the glass of color filter layer 32 may extend to edge location 99. The outermost edges of layers 42 and 74 may be configured to be inboard from edge 99 prior to etching. In particular, photolithographic processing techniques may be used to pattern layers 42 and 74 so that a gap G is formed between outermost edge 99 of color filter layer 32 and the outermost edges of layers 74 and 42.

Layers 42 and 74 may be formed from a photoimageable polymer that allows layers 42 and 74 to be patterned using photolithography. For example, overcoat layer 74 may be formed from a photoimageable acrylic material. The size of gap G may be 20 μm or any other suitable size (i.e., an amount equal to the expected amount of glass to be removed from layer 32 during HF etching). Following exposure to HF (e.g., during step 94 of FIG. 6), portions of the glass in layers 30 and 32 will be removed so that the outermost edge of color filter layer 32 will be aligned with the outermost edges of black masking layer 42 and acrylic overcoat layer 74, as shown by aligned edges 100 in FIG. 8. If desired, display 14 of FIGS. 7 and 8 may be provided with a spacer such as spacer 78. The configuration of FIGS. 7 and 8 in which no spacer is present is merely an example.

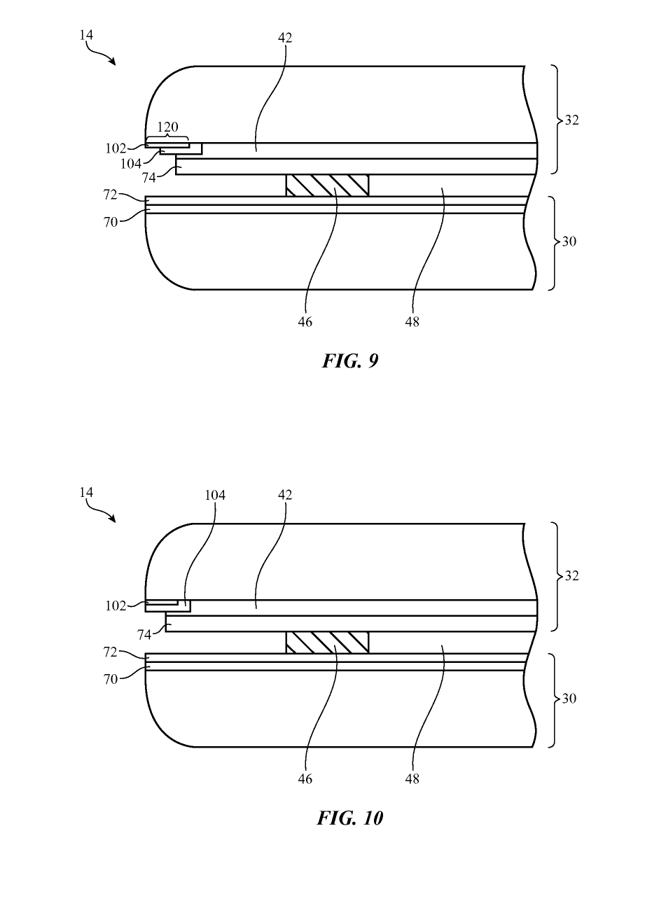

In the illustrative configuration FIG. 9, a portion of the opaque masking layer for display 14 has been formed from a peripheral metal layer (e.g., a rectangular ring-shaped strip of metal that runs along the edges of display 14). As shown in FIG. 9, edge portion 120 of color filter layer 32 may be coated with metal layer 102. Metal layer 102 may be formed from a metal such as titanium, molybdenum, or other metal(s). Metal layer 102 is opaque and therefore may serve as an extended portion of opaque masking layer 42.

To prevent electrostatic charge from disrupting operation of display 14, it may be desirable to place an intervening dielectric layer between metal layer 102 and black masking layer 42. For example, dielectric layer 104 may overlap metal layer 102 and black masking layer 42 may be formed from a black polymer layer that overlaps dielectric layer 104 without contacting metal layer 102. With this type of configuration, electrostatic charge that is deposited on layer 102 (e.g., due to contact with a user's finger or other source of static electricity), will not be conducted from metal layer 102 to black masking layer 42 and will therefore not disrupt electric fields within liquid crystal layer 48.

Dielectric layer 104 may be formed from an inorganic dielectric such as silicon nitride, silicon oxide, or silicon oxynitride, or may be formed from other dielectric material. To prevent portions of metal layer 120 from protruding out from under color filter layer 32 following etching at step 94 (FIG. 6), it may be desirable to form metal layer 102 from a metal material that can be etched during the etching of the glass of color filter layer 32. For example, if HF is being used as an etchant to etch the glass of color filter layer 32, metal layer 102 may be formed from a material such as titanium that can be effectively etched by HF. Dielectric 104 may also be formed from a material that is etched by HF (e.g. silicon oxide). With this type of approach, the outermost edge of layers 102 and 104 will be etched along with the glass of color filter layer 32, so that no portion of metal layer 102 or dielectric 104 will protrude out from under the glass of color filter layer 32 following HF etching (see, e.g., FIG. 10).

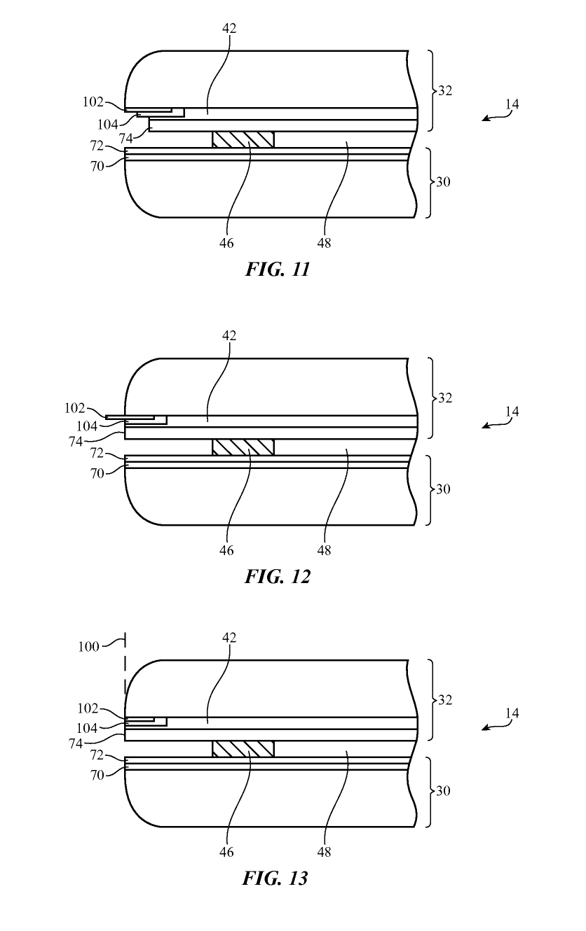

Another illustrative arrangement for preventing portions of the opaque masking layer from protruding out from under the edge of the glass of color filter 32 is shown in FIGS. 11, 12, and 13. With this type of approach, metal layer 102 may be formed from a metal of the type that is etched by a different etchant than the etchant that is used to etch the glass of color filter layer 32. As an example, metal layer 102 may be formed from a metal such as molybdenum. Molybdenum can be etched using an etchant such as silicon isotropic etchant (SIE). An example of a silicon isotropic etchant is an etchant formed from a mixture of hydrofluoric, nitric, and acetic acids. This etchant will etch metal layer 102 without significantly etching the glass of color filter layer 32. Other etchants that are suitable for etching metal layer 102 without etching the glass of color filter layer 32 may be used, if desired.

In the configuration of FIG. 11, the black masking layer on the underside of color filter layer 32 is formed by creating a layer of metal 102 (e.g., molybdenum) along the outermost edge of the glass substrate for color filter layer 32. Dielectric layer 104 may overlap the inner edge of layer 102. A photoimageable polymer may be used to form black masking layer 42 and may overlap dielectric layer 104. Prior to etching the glass of layer 32 with HF, metal layer 102 will not protrude outwardly from the edge of the glass, as shown in FIG. 11. However, after etching layer 32 with HF, some of the glass of color filter layer 32 will be removed, which will expose the outer portion of layer 102. As a result, metal layer 102 will temporarily have a laterally protruding portion, as shown in FIG. 12. This protruding portion of metal layer 102 may be unsightly. Accordingly, display 14 is preferably exposed to an etchant that selectively etches away metal layer 102 (e.g., molybdenum) such as a silicon isotropic etch. When exposed to this type of etchant, metal layer 102 (e.g., molybdenum layer 102) will be etched until the outermost edge of layer 102 is aligned with the outermost edge of the glass layer in color filter layer 32, as shown by aligned edges 100 in FIG. 13. Removal of excess portions of metal layer 102 will help ensure that color filter layer 32 has an aesthetically pleasing appearance.

If desired, spacer 78 may be incorporated into displays of the type shown in FIGS. 11, 12, and 13 to help prevent damage to metal traces and other structures in display 14 during etching.

The foregoing is merely illustrative and various modifications can be made by those skilled in the art without departing from the scope and spirit of the described embodiments. The foregoing embodiments may be implemented individually or in any combination.

What is claimed is:

1. A display having a peripheral edge, comprising:
first and second display layers;
a ring of adhesive sealant that is interposed between the first and second display layers; and
a ring-shaped spacer that surrounds the ring of sealant and that runs along the peripheral edge of the display.

2. The display defined in claim 1, further comprising:
a layer of liquid crystal material between the first and second display layers, wherein the ring of adhesive sealant retains the liquid crystal material within the display between the first and second display layers.

3. The display defined in claim 2 wherein the first display layer comprises a color filter layer.

4. The display defined in claim 3 wherein the second display layer comprises a thin-film transistor layer.

5. The display defined in claim 4 further comprising column spacers on the color filter layer, wherein the ring-shaped spacer and the column spacers are formed from a common polymer layer.

6. The display defined in claim 5 wherein the polymer layer comprises a photoimageable polymer layer.

7. The display defined in claim 6 wherein the ring-shaped spacer is compressed between the color filter layer and the thin-film transistor layer and helps prevent liquid from reaching the ring of adhesive sealant.

8. The display defined in claim 7 further comprising a black masking layer on the color filter layer, wherein the color filter layer has a glass layer with an etched peripheral edge.

9. The display defined in claim 8 wherein the black masking layer comprises a black polymer layer having a peripheral edge that is aligned with the peripheral edge of the glass layer.

10. The display defined in claim 7 further comprising a metal layer having a peripheral edge that is aligned with the peripheral edge of the glass layer.

11. The display defined in claim 10 further comprising a dielectric layer that overlaps part of the metal layer and a black polymer layer that overlaps part of the dielectric layer.

12. A method for forming a liquid crystal display, comprising:
forming a display panel having a color filter layer, a thin-film transistor layer, a layer of liquid crystal material interposed between the color filter layer and the thin-film transistor layer, a ring of adhesive sealant that retains the liquid crystal material between the color filter layer and the thin-film transistor layer, and a polymer spacer having a ring shape that surrounds the ring of adhesive sealant;
grinding a peripheral edge of the color filter layer with a grinding tool; and
etching the peripheral edge of the color filter layer using an etchant, wherein the polymer spacer helps prevent the etchant from reaching the ring of adhesive sealant.

13. The method defined in claim 12 further comprising covering a thin-film transistor ledge region of the thin-film transistor layer during the etching.

14. The method defined in claim 13 wherein covering the thin-film transistor ledge portion comprises covering the thin-film transistor ledge region with a portion of the color filter layer.

15. The method defined in claim 14 further comprising removing the portion of the color filter layer that covered the thin-film transistor ledge region following the etching.

16. The method defined in claim 15 further comprising drilling at least one opening in the color filter layer before the etching.

17. The method defined in claim 16 further comprising simultaneously forming column spacers and the polymer spacer on the color filter layer using photolithography.

18. The method defined in claim 15 wherein removing the portion of the color filter layer that covered the thin-film transistor layer ledge region comprises using scribing and breaking techniques to remove the portion of the color filter layer.

19. A liquid crystal display, comprising:
a color filter layer having a glass substrate layer coated with a black masking layer;
a thin-film transistor layer having a glass substrate layer with thin-film transistor circuitry;
a layer of liquid crystal material interposed between the color filter layer and the thin-film transistor layer;
a ring of adhesive sealant that surrounds the layer of liquid crystal material and retains the liquid crystal material between the color filter layer and the thin-film transistor layer; and
a polymer spacer ring that surrounds the ring of adhesive sealant, wherein the ring of adhesive sealant is formed from a first material and the polymer spacer ring is formed from a second material that is different than the first material.

20. The liquid crystal display defined in claim 19 further comprising column spacers between the color filter layer and the thin-film transistor layer, wherein the column spacers are formed from the second material.

21. The with crystal display defined in claim 20 where in the first material is epoxy and wherein the second material is a photoimageable polymer.
